(19) United States
(12) Patent Application Publication
(10) Pub. No.: US 2025/0389999 A1
(43) Pub. Date: Dec. 25, 2025

(54) OPTICAL PATH CONTROL MEMBER AND DISPLAY DEVICE COMPRISING SAME

(71) Applicant: LG INNOTEK CO., LTD., Seoul (KR)

(72) Inventors: Chan Mi JU, Seoul (KR); Byung Sook KIM, Seoul (KR); Seung Jin KIM, Seoul (KR)

(21) Appl. No.: 18/879,535

(22) PCT Filed: May 15, 2023
(86) PCT No.: PCT/KR2023/006557

§ 371 Date: Dec. 27, 2024

(30) Foreign Application Priority Data
Jun. 27, 2022 (KR) 10-2022-0078343

(51) Int. Cl. G02F 1/16757; G02F 1/13; G02F 1/167; G02F 1/1685

(52) U.S. Cl. CPC G02F 1/16757; G02F 1/1323; G02F 1/167; G02F 1/1685

(57) ABSTRACT

An optical path control member according to an embodiment includes a first substrate; a first electrode disposed on the first substrate; a second substrate disposed on the first substrate; a second electrode disposed under the second substrate; and a light conversion part disposed between the first electrode and the second electrode, wherein the light conversion part includes a first region on the first electrode and a second region on the first region, and a permittivity of the first region is greater than a permittivity of the second region.

### TECHNICAL FIELD

An embodiment relates to an optical path control member and a display device including the same.

### BACKGROUND ART

A light blocking film blocks light from being transmitted from a light source. The light blocking film is attached to a front of a display panel, which is a display device used for a mobile phone, laptop, tablet PC, vehicle navigation, or vehicle touch screen. The light blocking film adjusts a viewing angle of light according to an angle of incidence of light when the display outputs a screen. As a result, the user can view clear image quality at the desired viewing angle.

In addition, light blocking film is used for windows in vehicles or buildings. Accordingly, the light blocking film can prevent glare by partially shielding external light. Alternatively, the light blocking film can make an inside invisible from an outside.

Meanwhile, the light blocking film can be divided into a light blocking film that can always control the viewing angle regardless of a surrounding environment, and a switchable light blocking film that allows the user to turn the viewing angle control on and off depending on the surrounding environment.

The switchable light blocking film includes a receiving part. A light conversion material is disposed inside the receiving part. The light conversion material includes particles and a dispersion liquid in which the particles are dispersed. The particles can move by applying voltage. Accordingly, the receiving part can be switched into a light transmitting portion or a light blocking portion.

Meanwhile, the receiving part can be formed by patterning a intaglio portion on a resin material. In addition, the light conversion material can be disposed inside the receiving part.

Accordingly, the light conversion material comes into contact with the resin material. Accordingly, an additive of the resin material can be introduced into the light conversion material. Accordingly, characteristics of the light conversion material can be changed. Accordingly, driving characteristics of the optical path control member can be reduced.

In addition, during a process of manufacturing the light blocking film, the resin material can be deformed by heat. As a result, the reliability of the optical path control member may be reduced.

Therefore, a new optical path control member having a structure that can solve the above problems is required.

### DISCLOSURE

### Technical Problem

An embodiment provides an optical path control member having improved driving characteristics and reliability.

### Technical Solution

An optical path control member according to an embodiment includes a first substrate; a first electrode disposed on the first substrate; a second substrate disposed on the first substrate; a second electrode disposed under the second substrate; and a light conversion part disposed between the first electrode and the second electrode, wherein the light conversion part includes a first region on the first electrode and a second region on the first region, and a permittivity of the first region is greater than a permittivity of the second region.

### Advantageous Effects

An optical path control member according to an embodiment includes a first region and a second region. The first region corresponds to a base part, and the second region corresponds to a partition wall part. A permittivity of the first region and a permittivity of the second region may be different. Accordingly, the base part and the partition wall part may have permittivities suitable for their respective positions.

In detail, the permittivity of the first region may be large. Accordingly, a voltage may easily move from the first electrode to the receiving part through the base part. Accordingly, driving characteristics of the optical path control member may be improved.

In addition, the permittivity of the second region may be small. Accordingly, the embodiment allows the electric field formation of the light conversion material not to be interfered with by the partition wall part. Accordingly, the driving characteristics of the optical path control member may be improved.

Therefore, the optical path control member according to an embodiment may have improved driving characteristics.

### DESCRIPTION OF DRAWINGS

FIG. 1 is a perspective view of an optical path control member according to an embodiment.

FIG. 2 and FIG. 3 are cross-sectional views taken along line A-A′ of FIG. 1.

FIG. 4 to FIG. 7 are enlarged views of region A of FIG. 3.

FIG. 8 and FIG. 9 are cross-sectional views of a display device to which an optical path control member according to an embodiment is applied.

FIG. 10 to FIG. 12 are drawings for explaining one embodiment of a display device to which an optical path control member according to an embodiment is applied.

### MODE FOR INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

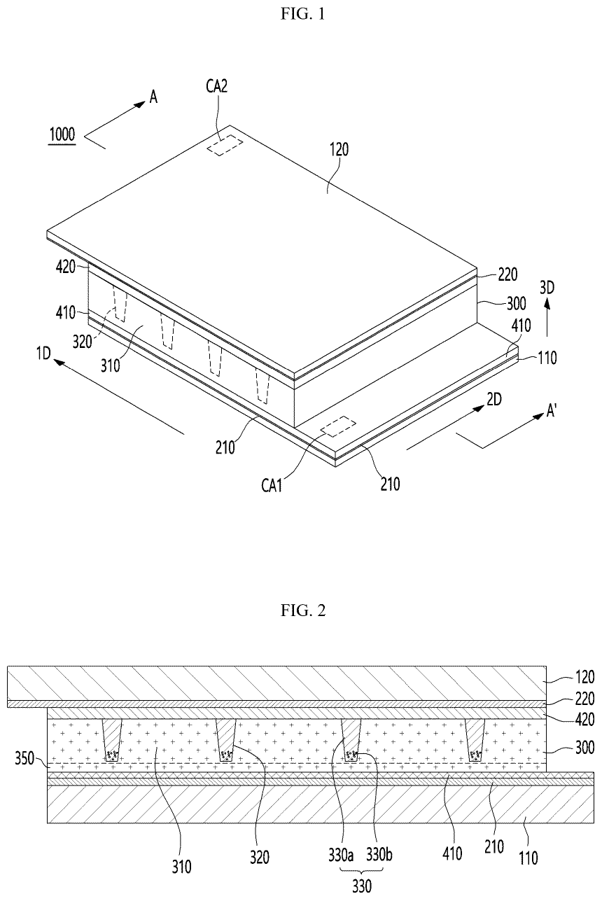

FIG. 1 is a perspective view of an optical path control member according to an embodiment.

Referring to FIG. 1, an optical path control member 1000 according to an embodiment includes a first substrate 110, a second substrate 120, a first electrode 210, a second electrode 220, and a light conversion part 300.

The first substrate 110 and the second substrate 120 may be rigid or flexible.

In addition, the first substrate 110 and the second substrate 120 may be transparent. For example, the first substrate 110 and the second substrate 120 may include a transparent substrate capable of transmitting light.

The first substrate 110 and the second substrate 120 may include glass, plastic, or a flexible polymer film. For example, the flexible polymer film may include polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, or polystyrene (PS).

In addition, the first substrate 110 and the second substrate 120 may be flexible substrates having flexible characteristics.

In addition, the first substrate 110 and the second substrate 120 may be curved or bent substrates. Accordingly, the optical path control member may have flexible, curved or bent characteristics. Therefore, the optical path control member according to the embodiment may be changed into various designs.

The first substrate 110 and the second substrate 120 may have a thickness within a set range. For example, the thickness of the first substrate 100 and the thickness of the second substrate 120 may be 30 μm to 100 μm. In detail, the thickness of the first substrate 110 and the thickness of the second substrate 120 may be 40 μm to 80 μm. More specifically, the thickness of the first substrate 110 and the thickness of the second substrate 120 may be 50 μm to 60 μm.

If the thickness of the first substrate 110 and the thickness of the second substrate 120 exceed 100 μm, an overall thickness and weight of the optical path control member may increase.

In addition, if the thickness of the first substrate 110 and the thickness of the second substrate 120 are less than 30 μm, an electrode is not sufficiently supported by the first substrate 110 and the second substrate 120.

The thickness of the first substrate 110 and the thickness of the second substrate 120 may be the same or similar within the above range.

The first electrode 210 and the second electrode 220 may include a transparent conductive material. For example, the first electrode 210 and the second electrode 220 may include a conductive material having a light transmittance of about 80% or more. For example, the first electrode 210 and the second electrode 220 may include a metal oxide. For example, the first electrode 210 and the second electrode 220 may include indium tin oxide, indium zinc oxide, copper oxide, tin oxide, zinc oxide, or titanium oxide.

Alternatively, the first electrode 210 and the second electrode 220 may include various metals to implement a small resistance. For example, the first electrode 210 and the second electrode 220 may include at least one metal among chromium (Cr), nickel (Ni), copper (Cu), aluminum (Al), silver (Ag), molybdenum (Mo), gold (Au), titanium (Ti), and alloys thereof.

The first electrode 210 and the second electrode 220 may have a thickness within a set range. For example, a thickness of the first electrode 210 and a thickness of the second electrode 220 may be 0.2 μm to 1 μm. In detail, the thickness of the first electrode 210 and the thickness of the second electrode 220 may be 0.2 μm to 0.5 μm.

If the thickness of the first electrode 210 and the thickness of the second electrode exceed 1 μm, the overall thickness and weight of the optical path control member may increase.

In addition, if the thickness of the first electrode 210 and the thickness of the second electrode 220 are less than 0.2 μm, the thickness of the first electrode 210 and the resistance of the second electrode 220 may increase. By this, the driving characteristics of the optical path control member can be reduced.

The thickness of the first electrode 210 and the thickness of the second electrode 220 can be the same or similar within the above range.

A connection electrode is disposed on each of the first substrate 110 and the second substrate 120. The connection electrode includes a first connection electrode CA1 and a second connection electrode CA2. The first connection electrode CA1 is formed by exposing the first electrode 210 on the first substrate 110. The second connection electrode CA2 is formed by exposing the second electrode 220 on the second substrate 120.

The optical path control member is electrically connected to an external (flexible) printed circuit board by the first connection electrode CA1 and the second connection region CA2.

For example, a pad part may be disposed on the first connection electrode CA1 and the second connection electrode CA2. A conductive adhesive may be disposed between the pad part and the (flexible) printed circuit board. The conductive adhesive may include an anisotropic conductive film (ACF) or anisotropic conductive paste (ACP). Accordingly, the pad part and the (flexible) printed circuit board may be connected.

Alternatively, the conductive adhesive may be disposed between the connection electrodes CA1 and CA2 and the (flexible) printed circuit board. Accordingly, the pad part and the (flexible) printed circuit board may be connected without a separate pad part.

The light conversion part 300 is disposed between the first substrate 110 and the second substrate 120. In detail, the light conversion part 300 is disposed between the first electrode 210 and the second electrode 220.

A buffer layer 410 is disposed between the light conversion part 300 and the first electrode 210. The buffer layer 410 improves an adhesion between the first electrode 220 and the light conversion part 300, which is a heterogeneous material. That is, the buffer layer 410 may be a primer layer disposed between the light conversion part 300 and the first electrode 210.

An adhesive layer 420 is disposed between the light conversion part 300 and the second electrode 220. The light conversion part 300 and the second electrode 220 can be adhered by the adhesive layer 420.

The buffer layer 410 and the adhesive layer 420 can include a transparent material capable of transmitting light. For example, the buffer layer 410 can include a transparent resin. In addition, the adhesive layer 420 can include an optically transparent adhesive (OCA).

The optical path control member can extend in a first direction 1D, a second direction 2D, and a third direction 3D.

The first direction 1D corresponds to a length or width direction of the optical path control member. The second direction 2D corresponds to a length or width direction of the optical path control member. The second direction 2D is different from the first direction 1D. The third direction 3D corresponds to a thickness direction of the optical path control member. The third direction 3D is different from the first direction 1D and the second direction 2D.

For example, the first direction 1D may be defined in the length direction of the optical path control member. In addition, the second direction 2D may be defined in the width direction of the optical path control member. In addition, the third direction 3D may be defined in the thickness direction of the optical path control member.

Alternatively, the first direction 1D may be defined in the width direction of the optical path control member. In addition, the second direction 2D may be defined in the length direction of the optical path control member. In addition, the third direction 3D may be defined in the thickness direction of the optical path control member.

Hereinafter, for convenience of explanation, the first direction 1D is defined as the length direction of the optical path control member. In addition, the second direction 2D is defined as the width direction of the optical path control member. In addition, the third direction 3D is defined as the thickness direction of the optical path control member.

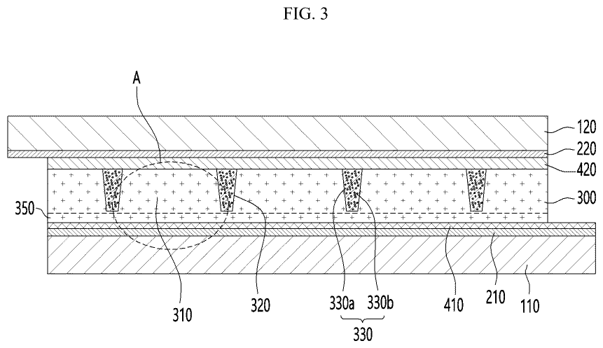

FIGS. 2 and 3 are cross-sectional views taken along line A-A′ of FIG. 1.

Referring to FIG. 2 and FIG. 3, the light conversion part 300 includes a plurality of partition wall parts 310, a plurality of receiving parts 320, and a base part 350.

The partition wall parts 310 and the receiving parts 320 are disposed alternately. That is, one receiving part 320 is disposed between two adjacent partition wall parts 310. In addition, one partition wall part 310 is disposed between two adjacent receiving parts 320.

The base part 350 is disposed below the receiving part 320. In detail, the base part 350 is disposed between the receiving part 320 and the buffer layer 410. More specifically, the base part 350 is disposed between a lower surface of the receiving part 320 and an upper surface of the buffer layer 410. Accordingly, the light conversion part 300 is adhered to the first electrode 210 by the base part 350 and the buffer layer 410.

In addition, an adhesive layer 420 is disposed between the partition wall part 310 and the second electrode 220. The light conversion part 300 and the second electrode 220 are adhered by the adhesive layer 420.

The partition wall part 310 and the receiving part 320 include a resin material. A mold member is imprinted on the resin material. The base part 350 is formed while the mold member is released. Accordingly, the base part 350 and the partition wall part 310 include a same material. That is, the base part 350 and the partition wall part 310 are formed integrally.

The base part 350 may have a thickness within a set range. For example, a thickness of the base part 350 may be 10% or less of a thickness of the light conversion part. In detail, the thickness of the base part 350 may be 5% to 10% of the thickness of the light conversion part. In detail, the thickness of the base part 350 may be 6% to 9% of the thickness of the light conversion part.

If the thickness of the base part 350 exceeds 10% of the thickness of the light conversion part, a distance between the receiving part 320 and the first electrode 210 increases. Accordingly, a voltage applied to the receiving part may decrease. Accordingly, driving characteristics of the optical path control member may decrease.

The resin material may include a resin composition. The resin composition may include an oligomer, a monomer, a photopolymerization initiator, and an additive. A prepolymer in a high molecular form and a multifunctional monomer and a photopolymerization initiator as a diluent react. The resin composition is cured by the reaction to form a resin layer. An intaglio portion in a shape of the receiving part is formed in the resin layer. Accordingly, the partition wall part 310, the receiving part, and the base part 350 are formed. In addition, the partition wall part 310 and the base part 350 have permittivities within a set range.

The partition wall part 310 can transmit light. In addition, the receiving part 320 can change the light transmittance according to application of voltage.

A light conversion material 330 is disposed inside the receiving part 320. The light transmittance of the receiving part 320 can change by the light conversion material 330. The light conversion material 330 includes light conversion particles 330b and a dispersion liquid 330a dispersing the light conversion particles 330b. The light conversion particles 330b move by the voltage application. In addition, the light conversion material 300 can further include a dispersant. The dispersant can prevent aggregation of the light conversion particles 330b.

The light conversion particles 330b move by the voltage application. Referring to FIG. 2, surfaces of the light conversion particles 330b are negatively charged. When a positive voltage is applied to the first electrode 210 and the second electrode 220, the light conversion particles 330b move toward the first electrode 210 or the second electrode 220. Thereby, the receiving part 320 becomes a light transmitting portion.

Referring to FIG. 3, when a negative voltage is applied to the first electrode 210 and the second electrode 220, the light conversion particles 330b are dispersed again into the dispersion 330a. Thereby, the receiving part 320 becomes a light blocking portion.

In addition, when no voltage is applied to the first electrode 210 and the second electrode 220, the light conversion particles 330b are dispersed inside the dispersion 330a. Thereby, the receiving part 320 maintains a state of the light blocking portion.

As described above, the light conversion part 300 includes a resin composition. That is, the light conversion part 300 includes a resin layer that is cured by the resin composition.

The partition wall part 310 and the base part 350 each have permittivity.

The partition wall part 310 is disposed adjacent to the receiving part 320 receiving the light conversion material 330. Therefore, it is advantageous for the partition wall part 310 to have a small permittivity. That is, as a permittivity of the partition wall part 310 decreases, driving characteristics of the light conversion material 300 disposed inside the receiving part 320 can be improved.

In addition, it is advantageous for the base part 350 to have a large permittivity. That is, the base part 350 is disposed adjacent to the first electrode 210. Accordingly, as the permittivity of the base part 350 increases, a movement of the voltage moving in a direction toward the receiving part 320 can be facilitated.

Hereinafter, an optical path control member that can solve the above problem is described.

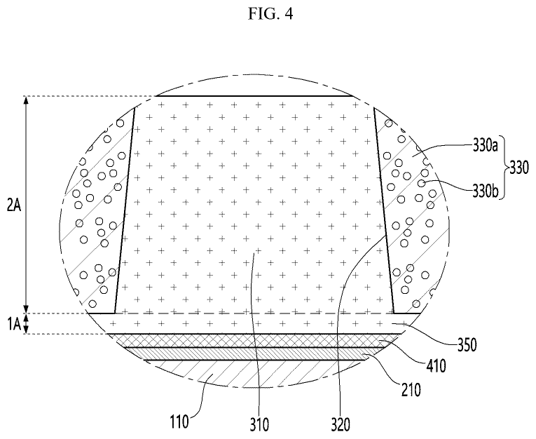

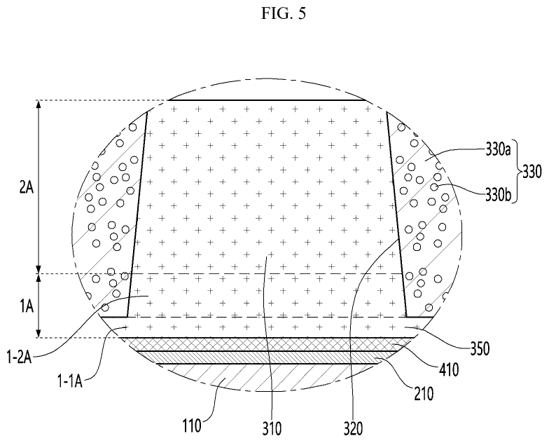

FIGS. 4 to 7 are enlarged views of region A of FIG. 3.

Referring to FIG. 4, the light conversion part 300 includes a plurality of regions. In detail, the light conversion part 300 includes a first region 1A and a second region 2A. The second region 2A is disposed on the first region 1A. The first region 1A is disposed closer to the first electrode 210 than the second region 2A. That is, the first region 1A is disposed on the first electrode 210, and the second region 2A is disposed on the first region 1A.

A thickness of the first region 1A and a thickness of the second region 2A are different. In detail, the thickness of the first region 1A is smaller than the thickness of the second region 2A.

The first region 1A may be defined as a region corresponding to the base part 350. The second region 2A may be defined as a region corresponding to the partition wall part 310.

The first region 1A and the second region 2A have different permittivities. In detail, a permittivity of the first region 1A is greater than a permittivity of the second region 2A.

For example, the permittivity of the first region 1A may be 6 or more. In detail, the permittivity of the first region 1A may be 10 or more. In more detail, the permittivity of the first region 1A may be 20 or more. In more detail, the permittivity of the first region 1A may be 30 or more. In more detail, the permittivity of the first region 1A may be 40 or more. In more detail, the permittivity of the first region 1A may be 10 to 60.

If the permittivity of the first region 1A is less than 10, the voltage applied from the first electrode 210 is not easily transmitted toward the receiving part 320. As a result, the driving characteristics of the optical path control member may be reduced.

In addition, if the permittivity of the first region 1A is greater than 60, a resin composition of the light conversion part 300 is limited to a composition having a specific composition. Accordingly, the process efficiency may be reduced.

The permittivity of the second region 2A may be 5 or less. In detail, the permittivity of the second region 2A may be 4 or less. More specifically, the permittivity of the second region 2A may be 3 or less. In more detail, the permittivity of the second region 2A may be 1 to 5.

If the permittivity of the second region 2A exceeds 5, there may be a problem that the electric field formed by the receiving part 320 is interfered with by the second region 2A. As a result, the driving characteristics of the optical path control member may be reduced. In addition, if the permittivity of the second region 2A is less than 1, the resin composition of the light conversion part 300 is limited to a composition having a specific composition. As a result, the process efficiency may be reduced.

In addition, a difference in permittivity between the first region 1A and the second region 2A has a set range. In detail, the difference in permittivity between the first region 1A and the second region 2A may be 3 or more. That is, the difference in permittivity between the first region 1A and the second region 2A can be 3 or more within the range of permittivity described above.

If the difference in permittivity between the first region 1A and the second region 2A is less than 3, the driving characteristics of the optical path control member may decrease.

The optical path control member according to the embodiment has different permittivities between the first region and the second region. The first region corresponds to the base part, and the second region corresponds to the partition wall part. Accordingly, the base part and the partition wall part may have permittivities suitable for their respective positions.

In detail, the permittivity of the first region may be large. Accordingly, a voltage may easily move from the first electrode to the receiving part through the base part. Accordingly, driving characteristics of the optical path control member may be improved.

In addition, the permittivity of the second region may be small. Accordingly, the embodiment allows the electric field formation of the light conversion material not to be interfered with by the partition wall part. Accordingly, the driving characteristics of the optical path control member may be improved.

Therefore, the optical path control member according to an embodiment may have improved driving characteristics

Referring to FIG. 5, the light conversion part 300 includes a plurality of regions. In detail, the light conversion part 300 includes a first region 1A and a second region 2A. The second region 2A is disposed on the first region 1A. The first region 1A is disposed closer to the first electrode 210 than the second region 2A.

A thickness of the first region 1A and a thickness of the second region 2A are different. In detail, the thickness of the first region 1A is smaller than the thickness of the second region 2A.

The first region 1A can be divided into a plurality of regions. In detail, the first region 1A includes a first-first region 1-1A and a first-second region 1-2A. The first-second region 1-2A is disposed between the first-first region 1-1A and the second region 2A.

A thickness of the first-first region 1-1A and a thickness of the first-second region 1-2A may be different. In detail, the thickness of the first-first region 1-1A may be smaller than the thickness of the first-second region 1-2A.

The first region 1A may be defined as a region corresponding to the base part 350 and the partition wall part 310. In detail, the first-first region 1-1A may be defined as a region corresponding to the base part 350. In addition, the first-second region 1-2A may be defined as a region corresponding to the partition wall part 310. In addition, the second region 2A may be defined as a region corresponding to the partition wall part 310.

The first-first region 1-1A, the first-second region 1-2A, and the second region 2A may have different permittivities. In detail, the first-first region 1-1A and the first-second region 1-2A may have a same or similar permittivity. In addition, a permittivity of the first-first region 1-1A and a permittivity of the first-second region 1-2A may be greater than the permittivity of the second region 2A.

For example, the permittivity of at least one region among the first-first region 1-1A and the first-second region 1-2A may be 6 or more, 10 or more, 20 or more, 30 or more, or 40 or more. More specifically, the permittivity of at least one region among the first-first region 1-1A and the first-second region 1-2A may be 10 to 60.

If the permittivity of the first-first region 1-1A and the permittivity of the first-second region 1-2A is less than 10, the voltage applied from the first electrode 210 is not easily transmitted toward the receiving part 320. By this, the driving characteristics of the optical path control member may be reduced.

In addition, if the permittivity of the first-first region 1-1A and the permittivity of the first-second region 1-2A exceeds 60, the resin composition of the light conversion part 300 is limited to a composition having a specific composition. Accordingly, the process efficiency may be reduced.

The permittivity of the second region 2A may be 5 or less. In detail, the permittivity of the second region 2A may be 4 or less. More specifically, the permittivity of the second region 2A may be 3 or less. More specifically, the permittivity of the second region 2A may be 1 to 5.

If the permittivity of the second region 2A exceeds 5, there may be a problem that the electric field formed by the receiving part 320 is interfered with by the second region 2A. By this, the driving characteristics of the optical path control member may be reduced. In addition, if the permittivity of the second region 2A is less than 1, the resin composition of the light conversion part 300 is limited to a composition having a specific composition. Accordingly, the process efficiency may be reduced.

In addition, the difference in permittivity between the first region 1A and the second region 2A has a set range. In detail, the difference in permittivity between the first region 1A and the second region 2A may be 3 or more. That is, the difference in permittivity between the first region 1A and the second region 2A may be 3 or more within the range of permittivity described above.

If the difference in permittivity between the first region 1A and the second region 2A is less than 3, the driving characteristics of the optical path control member may be reduced.

The first-second region 1-2A may be formed with a thickness within a set range. In detail, a thickness of the first-second region 1-2A may be 10% or less of a thickness of the partition wall part. In more detail, the thickness of the first-second region 1-2A may be 5% or less of the thickness of the partition wall part. In more detail, the thickness of the first-second region 1-2A may be 1% to 10% of the thickness of the partition wall part.

If the thickness of the first-second region 1-2A exceeds 10% of the thickness of the partition wall part, the permittivity of the partition wall part 310 increases. As a result, the driving characteristics of the optical path control member may decrease. In addition, it may be difficult to implement a process for controlling the thickness of the first-second region 1-2A to less than 1% of the thickness of the partition wall part.

According to the embodiment, the optical path control member has different permittivities of the first-first region, the first-second region, and the second region. Accordingly, the base part and the partition wall part can have permittivities suitable for each position.

That is, the permittivity of the first-first region can be large. Accordingly, the voltage can easily move from the first electrode to the receiving part direction through the base part. Accordingly, the driving characteristics of the optical path control member can be improved.

In addition, the permittivity of the second region corresponding to the partition wall part can be small. Accordingly, the embodiment allows the electric field formation of the light conversion material not to be interfered with by the partition wall part. Accordingly, the driving characteristics of the optical path control member may be improved.

In addition, the first-second region can be formed at a set ratio with respect to an entire thickness of the partition wall part. Accordingly, the partition wall part and the base part having different permittivities can be easily formed. In addition, it is possible to prevent the permittivity of the partition wall part from increasing.

Therefore, the optical path control member according to the embodiment can have improved driving characteristics.

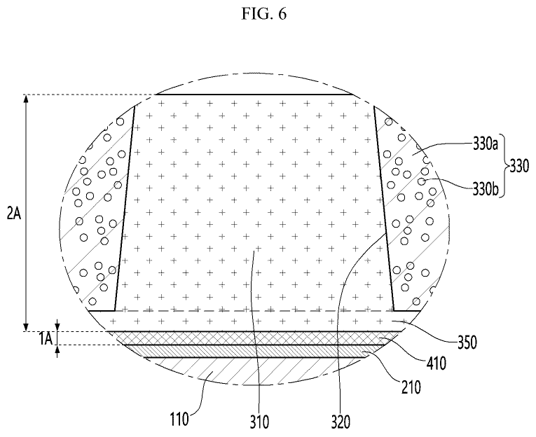

Referring to FIG. 6, the optical path control member includes a plurality of regions. In detail, the optical path control member includes a first region 1A and a second region 2A. The second region 2A is disposed on the first region 1A. The first region 1A is disposed closer to the first electrode 210 than the second region 2A.

A thickness of the first region 1A and a thickness of the second region 2A are different. In detail, the thickness of the first region 1A is smaller than the thickness of the second region 2A.

The first region 1A can be defined as a region corresponding to the buffer layer 410. The second region 2A can be defined as a region corresponding to the light conversion part 300. That is, the second region 2A can be defined as a region corresponding to the base part 350 and the partition wall part 310.

The first region 1A and the second region 2A may have different permittivities. In detail, the permittivity of the first region 1A may be greater than the permittivity of the second region 2A.

In detail, the permittivity of the first region 1A and the permittivity of the second region 2A may be the same as or similar to the permittivity described with reference to FIG. 4. In addition, the difference in permittivity between the first region 1A and the second region 2A may be the same as or similar to the difference in permittivity described with reference to FIG. 4.

The optical path control member according to the embodiment has different permittivities of the first region and the second region. The first region corresponds to the buffer layer. The second region corresponds to the light conversion part. Accordingly, the voltage can easily move from the first electrode to the receiving part through the buffer layer. Accordingly, the driving characteristics of the optical path control member can be improved.

In addition, the permittivity of the second region can be small. Accordingly, the embodiment allows the electric field formation of the light conversion material not to be interfered with by the partition wall part. Accordingly, the driving characteristics of the optical path control member may be improved.

Therefore, the optical path control member according to the embodiment can have improved driving characteristics.

In addition, the buffer layer has a large permittivity. Therefore, the light conversion part is disposed without controlling the permittivity. Accordingly, the process efficiency of the optical path control member can be improved.

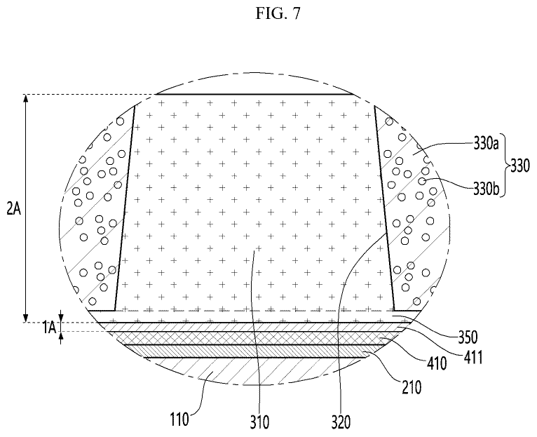

Referring to FIG. 7, the optical path control member includes a plurality of regions. In detail, the optical path control member includes a first region 1A and a second region 2A. The second region 2A is disposed on the first region 1A. The first region 1A is disposed closer to the first electrode 210 than the second region 2A.

The thickness of the first region 1A and the thickness of the second region 2A are different. In detail, the thickness of the first region 1A is smaller than the thickness of the second region 2A.

The first region 1A is disposed on the buffer layer 410. The first region 2A may be defined as a region corresponding to an intermediate layer 411. The intermediate layer 411 is disposed between the buffer layer 410 and the light conversion part 300. The second region 2A may be defined as a region corresponding to the light conversion part 300. That is, the second region 2A may be defined as a region corresponding to the base part 350 and the partition wall part 310.

The first region 1A and the second region 2A may have different permittivities. In detail, the permittivity of the first region 1A may be greater than the permittivity of the second region 2A.

In detail, the permittivity of the first region 1A and the second region 2A may be the same as or similar to the permittivity described with reference to FIG. 4. In addition, the difference in permittivity between the first region 1A and the second region 2A may be the same as or similar to the difference in permittivity described with reference to FIG. 4.

The optical path control member according to the embodiment includes the intermediate layer. The intermediate layer has a large permittivity. The intermediate layer is disposed on the buffer layer. Accordingly, the first region and the second region may have different permittivities. Accordingly, the voltage can easily move from the first electrode to the receiving part direction through the buffer layer. Accordingly, the driving characteristics of the optical path control member can be improved.

In addition, the permittivity of the second region can be small. Accordingly, the embodiment allows the electric field formation of the light conversion material not to be interfered with by the partition wall part. Accordingly, the driving characteristics of the optical path control member may be improved.

Therefore, the optical path control member according to the embodiment can have improved driving characteristics.

In addition, the intermediate layer having a large permittivity is disposed on the buffer layer. Therefore, the light conversion part is disposed without controlling the permittivity. Accordingly, the process efficiency of the optical path control member can be improved.

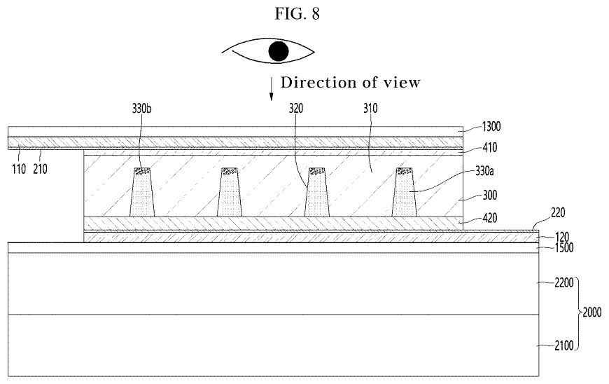

Hereinafter, a display device and a display device to which an optical path control member according to an embodiment is applied will be described with reference to FIGS. 8 to 12.

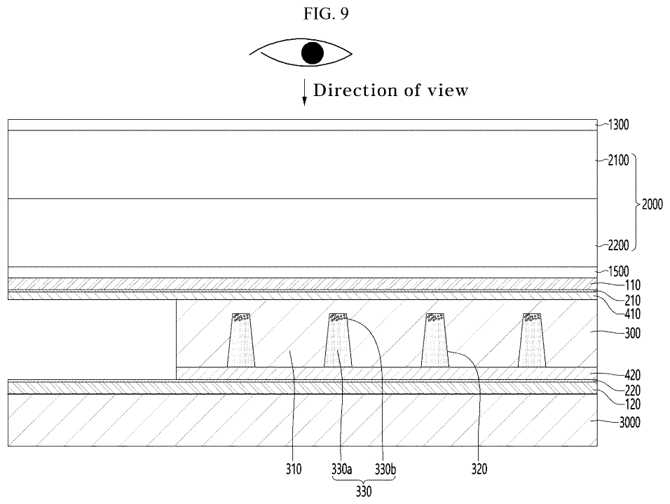

Referring to FIGS. 8 and 9, the optical path control member 1000 according to the embodiment may be disposed on or below the display panel 2000.

The display panel 2000 and the optical path control member 1000 may be disposed to be adhered to each other. For example, the display panel 2000 and the optical path control member 1000 may be adhered to each other via an adhesive member 1500. The adhesive member 1500 may be transparent. For example, the adhesive member 1500 may include an adhesive or an adhesive layer including a light transparent adhesive material.

The adhesive member 1500 may include a release film. In detail, when adhering the optical path control member and the display panel, the release film is removed. Accordingly, the optical path control member and the display panel may be adhered.

The display panel 2000 may include a first base substrate 2100 and a second base substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first base substrate 2100 including a thin film transistor (TFT) and a pixel electrode and the second base substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is bonded to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 9, the optical path control member may be disposed under the liquid crystal panel and on the backlight unit 3000, and the optical path control member may be disposed between the backlight unit 3000 and the display panel 2000.

Alternatively, as shown in FIG. 8, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

That is, light emitted from the display panel 2000 or the backlight unit 3000 can move from the second substrate 120 of the optical path control member toward the first substrate 110.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be a linear polarizing plate. Further, when the display panel 2000 is the organic light emitting diode panel, the polarizing plate may be an external light reflection preventing polarizing plate.

In addition, an additional functional layer 1300 such as an anti-reflection layer, an anti-glare, or the like may be further disposed on the optical path control member 1000. Specifically, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

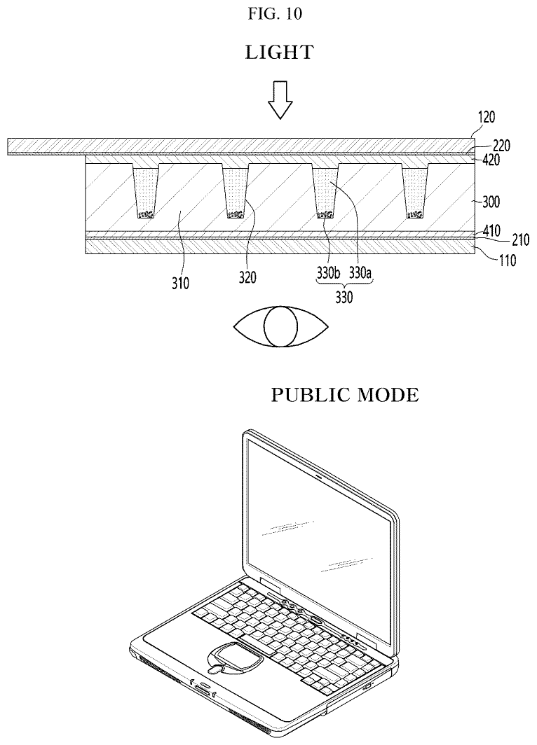

Referring to FIGS. 10 to 12, the optical path control member according to the embodiment may be applied to a display device that displays a display.

Referring to FIGS. 10 to 12, the optical path control member according to an embodiment may be applied to a display device that displays a display.

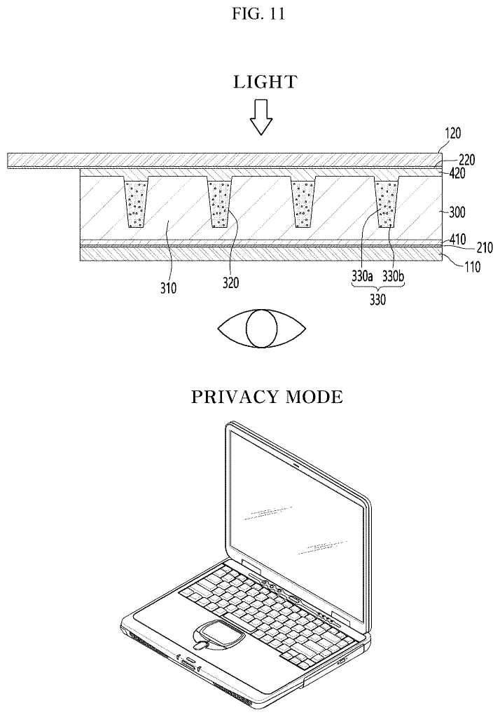

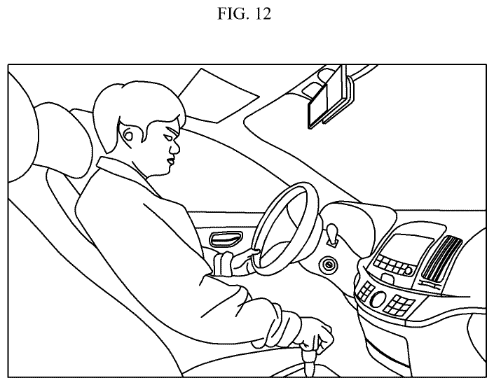

For example, when power is applied to the optical path control member as shown in FIG. 10, the receiving part functions as the light transmitting part, so that the display device may be driven in the public mode, and when power is not applied to the optical path control member as shown in FIG. 11, the receiving part functions as the light blocking part, so that the display device may be driven in the light blocking mode.

Accordingly, a user may easily drive the display device in a privacy mode or a normal mode according to application of power.

Light emitted from the backlight part or the self-luminous element may move from the first substrate toward the second substrate. Alternatively, the light emitted from the backlight part or the self-luminous element may also move from the second substrate toward the first substrate.

In addition, referring to FIG. 12, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a first electrode disposed on the first substrate;
a second substrate disposed on the first substrate;
a second electrode disposed under the second substrate; and
a light conversion part disposed between the first electrode and the second electrode,
wherein the light conversion part includes a first region on the first electrode and a second region on the first region, and
wherein a permittivity of the first region is greater than a permittivity of the second region.

2. The optical path control member of claim 1, wherein the permittivity of the first region is 10 to 60,
wherein the permittivity of the second region is 1 to 5, and
wherein a difference in permittivity between the first region and the second region is 3 or more.

3. The optical path control member of claim 2, wherein the light conversion part includes a base part and a partition wall part and a receiving part on the base part,
wherein a light conversion material is disposed inside the receiving part,
wherein the first region corresponds to the base part, and
wherein the second region corresponds to the partition wall part.

4. The optical path control member of claim 3, wherein the first region includes a first-first region on the first electrode and a first-second region on the first-first region,
wherein the first-first region corresponds to the base part, and
wherein the first-second region corresponds to the partition wall part.

5. The optical path control member of claim 4, wherein a thickness of the first-second region is 1% to 10% of a thickness of the partition wall part.

6. An optical path control member comprising:
a first substrate;
a first electrode disposed on the first substrate;
a second substrate disposed on the first substrate;
a second electrode disposed under the second substrate;
a light conversion part disposed between the first electrode and the second electrode; and
a buffer layer disposed between the first electrode and the light conversion part,
wherein the light conversion part includes a base part, and a partition wall part and a receiving part on the base part,
wherein a light conversion material is disposed inside the receiving part, and
wherein a permittivity of the buffer layer is greater than a permittivity of the light conversion part.

7. The optical path control member of claim 6, wherein the permittivity of the buffer layer is 10 to 60,
wherein the permittivity of the light conversion part is 1 to 5, and
wherein a difference in permittivity between the buffer layer and the light conversion part is 3 or more.

8. An optical path control member comprising:
a first substrate;
a first electrode disposed on the first substrate;
a second substrate disposed on the first substrate;
a second electrode disposed under the second substrate;
a light conversion part disposed between the first electrode and the second electrode;
a buffer layer disposed between the first electrode and the light conversion part; and
an intermediate layer disposed between the buffer layer and the first electrode light conversion part,
wherein the light conversion part includes a base part, and a partition wall part and a receiving part on the base part,
wherein a light conversion material is disposed inside the receiving part, and
wherein a permittivity of the intermediate layer is greater than a permittivity of the light conversion part.

9. The optical path control member of claim 8, wherein the permittivity of the intermediate layer is 10 to 60,
wherein the permittivity of the light conversion part is 1 to 5, and
wherein a difference in permittivity between the intermediate layer and the light conversion part is 3 or more.

10. A display device comprising:
a panel including at least one of a display panel and a touch panel; and
an optical path control member according to claim 1 disposed on or under the panel.
